(19) United States
(12) Patent Application Publication
(10) Pub. No.: US 2026/0010693 A1
(43) Pub. Date: Jan. 8, 2026

(54) SYSTEMS AND METHODS FOR CONTEXTUAL CIRCUIT FUNCTIONALITY

(71) Applicant: CIRCUIT HOLDINGS, INC., Austin, TX (US)

(72) Inventors: Oeivind A. G. LOE, Austin, TX (US); George Tyson TUTTLE, Austin, TX (US)

(21) Appl. No.: 18/762,829

(22) Filed: Jul. 3, 2024

(51) Int. Cl. G06F 30/31

(52) U.S. Cl. CPC G06F 30/31

(57) ABSTRACT

Disclosed are systems and methods for a decision intelligence (DI)-based computerized framework that provides customized circuits that enable interactions for users with curated, network-hosted electronic resources, as they relate to a user(s). The disclosed framework provides mechanisms for circuit curation, dissemination, updating and/or sharing over a network based on deterministically compiled user-based and/or circuit-based contexts, which can enable consuming users to be provided with the most current, accurate digital information that is temporally, socially, logically and emotionally to the user's current intent when consuming content via their device(s). Thus, the framework deterministically computes a context, which can be a user-based and/or circuit-based context, that can be leveraged to provide and/or recommend information and/or actions to users over a network.

### FIELD OF THE DISCLOSURE

The present disclosure relates to an electronic information and resource management and dissemination system, and more particularly, to a decision intelligence (DI)-based computerized framework for deterministically computing a context, which can be a user-based and/or circuit-based context, which can be leveraged to provide and/or recommend information and/or actions to users over a network.

### SUMMARY OF THE DISCLOSURE

The disclosed systems and methods provide a novel computerized framework that operates to curate customized electronic resource experiences for users, which can include, but are not limited to, people (e.g., a person or group of people), entities, companies, government, agencies, cities, regions, and the like. For example, as discussed herein, the disclosed framework functions via computerized mechanisms to retrieve, extract, determine or otherwise identify information of interest and/or relation to a user, for example, and compile such information into a dynamic data structure for consumption by such user and/or other users, which may be availed access to the data structure via permissioned access, granted access to a request and/or subscription-based access rights, among others, as discussed herein.

According to some embodiments, the disclosed data structure, which can be an electronic content file and/or executable file, can be realized for display and/or consumption as, but not limited to, an application, web page, portal, browser, electronic message, interface, and/or other form of known or to be known electronic and/or digital file, object or item for which content can be collected, curated and consumed by permitted users (and/or other platforms).

As discussed herein, the disclosed data structure, referred to as a “circuit,” can be compiled as an electronic file displayed on a specific web page within a browser (and/or a browser user interface (UI), for example), whereby collected information related to a topic(s) for a user can be organized and presented for consumption to the user. Examples of such curation and operation are discussed below in more detail.

Accordingly, the disclosed systems and methods framework provides novel mechanisms for determining and leveraging a deep user-based and/or circuit-based context to automatically surface information and/or recommend information and/or actions that are temporally, spatially, socially, emotionally and/or logically relevant to a user and/or a particular circuit(s). As discussed in more detail below, such information and/or actions, which can be recommended and/or populated within displayed circuit interfaces can be related to, but not limited to, a user(s), a circuit, the user's interests, behaviors, geographical information, demographics, real-world activities, digital activities, topics, categories, preferences, other circuits, and the like, or some combination thereof. Accordingly, in some embodiments, the disclosed circuit framework can function to provide capabilities that enable the retrieval of data not previously available to users, which can enable enhanced information consumption, and improved interactions on/over the network, with other network resources and/or other users, and the like.

For purposes of this disclosure, it should be understood that while reference is made to users, it should not be construed as limited to people, as one of skill in the art would readily understand that a user can be, but is not limited to, a person, group, entity, virtual client, company, organization, government, agency, municipality, demographic, region, geographic area, and/or any other type of identifiable subject for which content can be customized for and provided to, as discussed herein, without departing from the scope of the instant disclosure.

According to some embodiments, the disclosed framework can generate, manage, share and host circuits via novel mechanisms that understand the current and/or future needs of users. Such novel mechanisms, as discussed in more detail below, can involve the integration and/or implementation of artificial intelligence (AI), machine learning (ML) and/or large language models (LLMs). As discussed in more detail below, collected data related to electronic resources, for example, can be analyzed via such known or to be known AI/ML models and/or LLMs, such that curated circuit information and/or actions events, as well as currently detected data related to current and/or ongoing circuit versions can determined therefrom. Accordingly, the disclosed framework can provide a dynamically adaptive, automated circuit building and hosting resource (e.g., application, web site, platform, for example) that can leverage generative software to control how and what types of data are provided to users and/or made available to users via their currently determined and/or predicted contexts, inter alia.

The latest transformer-based LLMs have, among other features and capabilities, theory of mind, abilities to reason, abilities to make a list of tasks, abilities to plan and react to changes (via reviewing their own previous decisions), abilities to understand multiple data sources (and types of data-multimodal), abilities to have conversations with humans in natural language, abilities to adjust, abilities to interact with and/or control application program interfaces (APIs), abilities to remember information long term, abilities to use tools (e.g., read multiple schedules/calendars, command other systems, search for data, and the like), abilities to use other LLM and other types of AI/ML (e.g., neural networks to look for patterns, recognize humans, pets, and the like, for example), abilities to check whether reports, ability to talk to other devices over standard device-to-device protocols, abilities to improve itself, abilities to correct mistakes and learn using reflection, and the like.

Thus, as provided herein, the disclosed integration of such AI/ML and/or LLM technology provides an improved framework for content generation and consumption over the Internet for all types and variations of users. As evidenced from the instant disclosure, this can lead to an improved content environment for a user (e.g., improved user experience), as well as an improved operational efficiency, resource management and management of network hosted data (e.g., improved key performance indicators (KPIs), for example).

According to some embodiments, a method is disclosed for a DI-based computerized framework for contextually, via user-based and/or circuit-based contexts, providing and/or recommending information and/or actions to users over a network. In accordance with some embodiments, the present disclosure provides a non-transitory computer-readable storage medium for carrying out the above-mentioned technical steps of the framework's functionality. The non-transitory computer-readable storage medium has tangibly stored thereon, or tangibly encoded thereon, computer readable instructions that when executed by a device cause at least one processor to perform a method for a DI-based computerized framework for contextually, via user-based and/or circuit-based contexts, providing and/or recommending information and/or actions to users over a network.

In accordance with one or more embodiments, a system is provided that includes one or more processors and/or computing devices configured to provide functionality in accordance with such embodiments. In accordance with one or more embodiments, functionality is embodied in steps of a method performed by at least one computing device. In accordance with one or more embodiments, program code (or program logic) executed by a processor(s) of a computing device to implement functionality in accordance with one or more such embodiments is embodied in, by and/or on a non-transitory computer-readable medium.

### DESCRIPTIONS OF THE DRAWINGS

The features, and advantages of the disclosure will be apparent from the following description of embodiments as illustrated in the accompanying drawings, in which reference characters refer to the same parts throughout the various views. The drawings are not necessarily to scale, emphasis instead being placed upon illustrating principles of the disclosure:

FIG. 1A is a block diagram of an example configuration within which the systems and methods disclosed herein could be implemented according to some embodiments of the present disclosure;

FIG. 1B is a block diagram illustrating components of an exemplary system according to some embodiments of the present disclosure;

FIG. 2 depicts a non-limiting example embodiment according to some embodiments of the present disclosure;

FIG. 3 depicts a non-limiting example embodiment according to some embodiments of the present disclosure;

FIG. 4 illustrates an exemplary work flow according to some embodiments of the present disclosure;

FIG. 5 illustrates an exemplary work flow according to some embodiments of the present

disclosure;

FIG. 6 illustrates an exemplary work flow according to some embodiments of the present disclosure;

FIG. 7 depicts an exemplary implementation of an architecture according to some embodiments of the present disclosure;

FIG. 8 depicts an exemplary implementation of an architecture according to some embodiments of the present disclosure; and

FIG. 9 is a block diagram illustrating a computing device showing an example of a client or server device used in various embodiments of the present disclosure.

### DETAILED DESCRIPTION

The present disclosure will now be described more fully hereinafter with reference to the accompanying drawings, which form a part hereof, and which show, by way of non-limiting illustration, certain example embodiments. Subject matter may, however, be embodied in a variety of different forms and, therefore, covered or claimed subject matter is intended to be construed as not being limited to any example embodiments set forth herein; example embodiments are provided merely to be illustrative. Likewise, a reasonably broad scope for claimed or covered subject matter is intended. Among other things, for example, subject matter may be embodied as methods, devices, components, or systems. Accordingly, embodiments may, for example, take the form of hardware, software, firmware or any combination thereof (other than software per se). The following detailed description is, therefore, not intended to be taken in a limiting sense.

Throughout the specification and claims, terms may have nuanced meanings suggested or implied in context beyond an explicitly stated meaning. Likewise, the phrase “in one embodiment” as used herein does not necessarily refer to the same embodiment and the phrase “in another embodiment” as used herein does not necessarily refer to a different embodiment. It is intended, for example, that claimed subject matter include combinations of example embodiments in whole or in part.

In general, terminology may be understood at least in part from usage in context. For example, terms, such as “and”, “or”, or “and/or,” as used herein may include a variety of meanings that may depend at least in part upon the context in which such terms are used. Typically, “or” if used to associate a list, such as A, B or C, is intended to mean A, B, and C, here used in the inclusive sense, as well as A, B or C, here used in the exclusive sense. In addition, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. In addition, the term “based on” may be understood as not necessarily intended to convey an exclusive set of factors and may, instead, allow for existence of additional factors not necessarily expressly described, again, depending at least in part on context.

The present disclosure is described below with reference to block diagrams and operational illustrations of methods and devices. It is understood that each block of the block diagrams or operational illustrations, and combinations of blocks in the block diagrams or operational illustrations, can be implemented by means of analog or digital hardware and computer program instructions. These computer program instructions can be provided to a processor of a general purpose computer to alter its function as detailed herein, a special purpose computer, ASIC, or other programmable data processing apparatus, such that the instructions, which execute via the processor of the computer or other programmable data processing apparatus, implement the functions/acts specified in the block diagrams or operational block or blocks. In some alternate implementations, the functions/acts noted in the blocks can occur out of the order noted in the operational illustrations. For example, two blocks shown in succession can in fact be executed substantially concurrently or the blocks can sometimes be executed in the reverse order, depending upon the functionality/acts involved.

For the purposes of this disclosure a non-transitory computer readable medium (or computer-readable storage medium/media) stores computer data, which data can include computer program code (or computer-executable instructions) that is executable by a computer, in machine readable form. By way of example, and not limitation, a computer readable medium may include computer readable storage media, for tangible or fixed storage of data, or communication media for transient interpretation of code-containing signals. Computer readable storage media, as used herein, refers to physical or tangible storage (as opposed to signals) and includes without limitation volatile and non-volatile, removable and non-removable media implemented in any method or technology for the tangible storage of information such as computer-readable instructions, data structures, program modules or other data. Computer readable storage media includes, but is not limited to, RAM, ROM, EPROM, EEPROM, flash memory or other solid state memory technology, optical storage, cloud storage, magnetic storage devices, or any other physical or material medium which can be used to tangibly store the desired information or data or instructions and which can be accessed by a computer or processor.

For the purposes of this disclosure the term “server” should be understood to refer to a service point which provides processing, database, and communication facilities. By way of example, and not limitation, the term “server” can refer to a single, physical processor with associated communications and data storage and database facilities, or it can refer to a networked or clustered complex of processors and associated network and storage devices, as well as operating software and one or more database systems and application software that support the services provided by the server. Cloud servers are examples.

For the purposes of this disclosure a “network” should be understood to refer to a network that may couple devices so that communications may be exchanged, such as between a server and a client device or other types of devices, including between wireless devices coupled via a wireless network, for example. A network may also include mass storage, such as network attached storage (NAS), a storage area network (SAN), a content delivery network (CDN) or other forms of computer or machine-readable media, for example. A network may include the Internet, one or more local area networks (LANs), one or more wide area networks (WANs), wire-line type connections, wireless type connections, cellular or any combination thereof. Likewise, sub-networks, which may employ differing architectures or may be compliant or compatible with differing protocols, may interoperate within a larger network.

For purposes of this disclosure, a “wireless network” should be understood to couple client devices with a network. A wireless network may employ stand-alone ad-hoc networks, mesh networks, Wireless LAN (WLAN) networks, cellular networks, or the like. A wireless network may further employ a plurality of network access technologies, including Wi-Fi, Long Term Evolution (LTE), WLAN, Wireless Router mesh, or 2nd, 3rd, 4th or 5th generation (2G, 3G, 4G or 5G) cellular technology, mobile edge computing (MEC), Bluetooth, 802.11b/g/n, or the like. Network access technologies may enable wide area coverage for devices, such as client devices with varying degrees of mobility, for example.

In short, a wireless network may include virtually any type of wireless communication mechanism by which signals may be communicated between devices, such as a client device or a computing device, between or within a network, or the like.

A computing device may be capable of sending or receiving signals, such as via a wired or wireless network, or may be capable of processing or storing signals, such as in memory as physical memory states, and may, therefore, operate as a server. Thus, devices capable of operating as a server may include, as examples, dedicated rack-mounted servers, desktop computers, laptop computers, set top boxes, integrated devices combining various features, such as two or more features of the foregoing devices, or the like.

For purposes of this disclosure, a client (or user, entity, subscriber or customer) device may include a computing device capable of sending or receiving signals, such as via a wired or a wireless network. A client device may, for example, include a desktop computer or a portable device, such as a cellular telephone, a smart phone, a display pager, a radio frequency (RF) device, an infrared (IR) device, virtual client, a Near Field Communication (NFC) device, a Personal Digital Assistant (PDA), a handheld computer, a tablet computer, a phablet, a laptop computer, a set top box, a wearable computer, smart watch, an integrated or distributed device combining various features, such as features of the forgoing devices, or the like.

A client device may vary in terms of capabilities or features. Claimed subject matter is intended to cover a wide range of potential variations, such as a web-enabled client device or previously mentioned devices may include a high-resolution screen (HD or 4K for example), one or more physical or virtual keyboards, mass storage, one or more accelerometers, one or more gyroscopes, global positioning system (GPS) or other location-identifying type capability, or a display with a high degree of functionality, such as a touch-sensitive color 2D or 3D display, for example.

Certain embodiments and principles will be discussed in more detail with reference to the figures. As discussed herein, in some embodiments, circuits can be public, secured, privately subscribed to, shared (e.g., publicly, per request, and/or per subscription), and the like, and can include interactive functionality that provides capabilities for the information included therein to be interacted with, acted upon and the like, as well as capabilities for interactions with other users and/or circuits. Accordingly, the disclosed systems and methods enable circuit curation, dissemination, updating and/or sharing over a network based on deterministically compiled user-based and/or circuit-based contexts, which can enable consuming users to be provided with the most current, accurate digital information that is temporally, socially, logically and emotionally to the user's current intent when consuming content via their device(s).

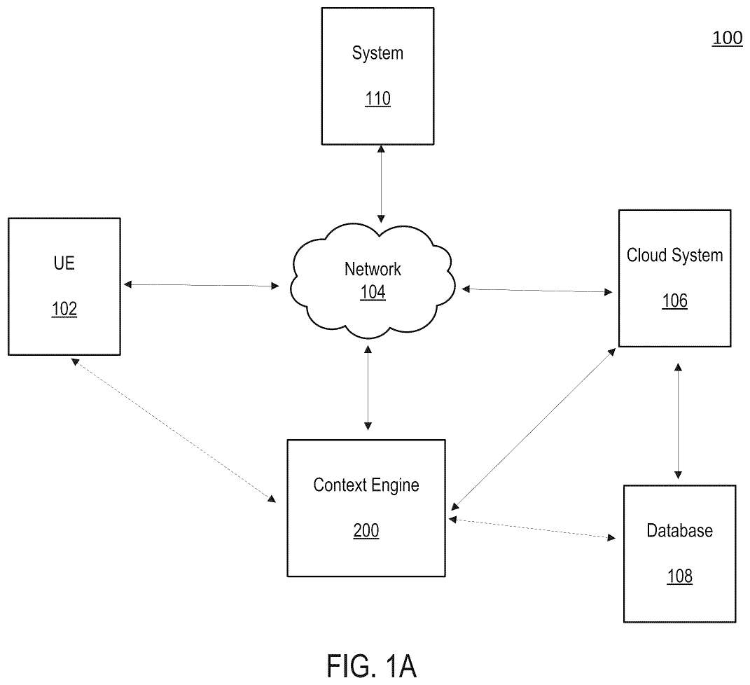

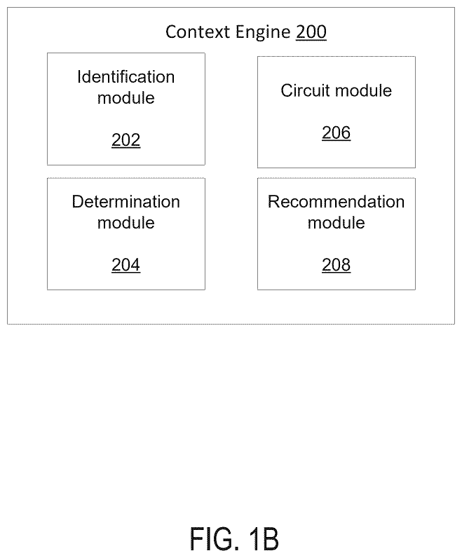

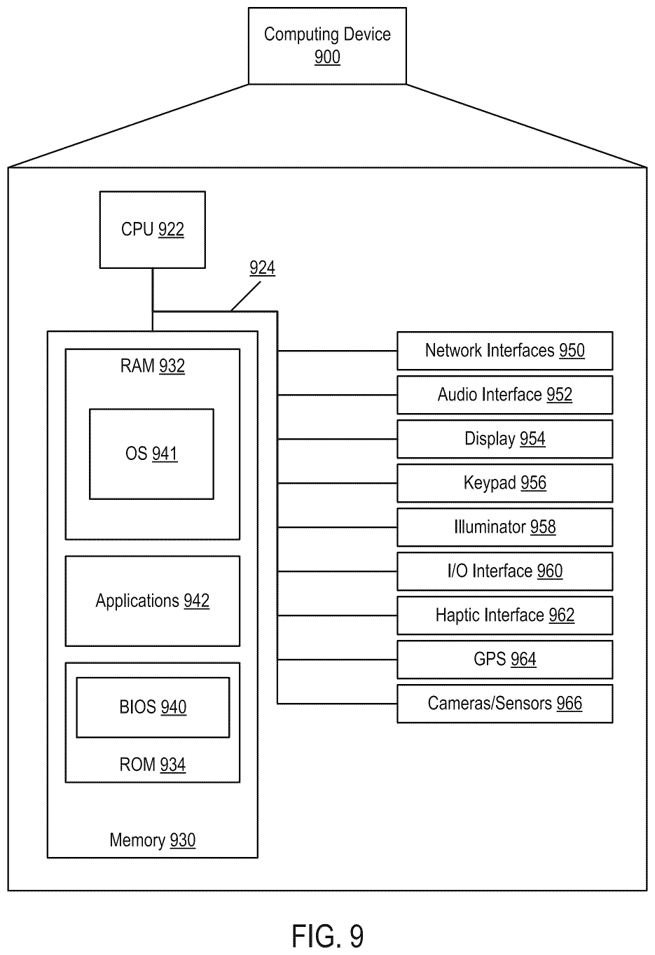

With reference to FIG. 1A, system 100 is depicted which includes user equipment (UE) 102 (e.g., a client device, as mentioned above and discussed below in relation to FIG. 9), system 110, network 104, cloud system 106, database 108 and context engine 200.

It should be understood that while system 100 is depicted as including such components, it should not be construed as limiting, as one of ordinary skill in the art would readily understand that varying numbers of UEs, devices, users/entities, systems, cloud systems, engines, databases and networks can be utilized; however, for purposes of explanation, system 100 is discussed in relation to the example depiction in FIG. 1A.

According to some embodiments, UE 102 can be any type of device, such as, but not limited to, a mobile phone, tablet, laptop, sensor, Internet of Things (IOT) device, wearable device, autonomous machine, smart television, media streaming device, game console, and any other device equipped with a cellular or wireless or wired transceiver.

In some embodiments, peripheral devices (not shown) can be connected to UE 102, and can be any type of peripheral device, such as, but not limited to, a wearable device (e.g., smart ring, smart watch, for example), printer, speaker, sensor, and the like. In some embodiments, a peripheral device can be any type of device that is connectable to UE 102 via any type of known or to be known pairing mechanism, including, but not limited to, WiFi, Bluetooth™, Bluetooth Low Energy (BLE), NFC, and the like.

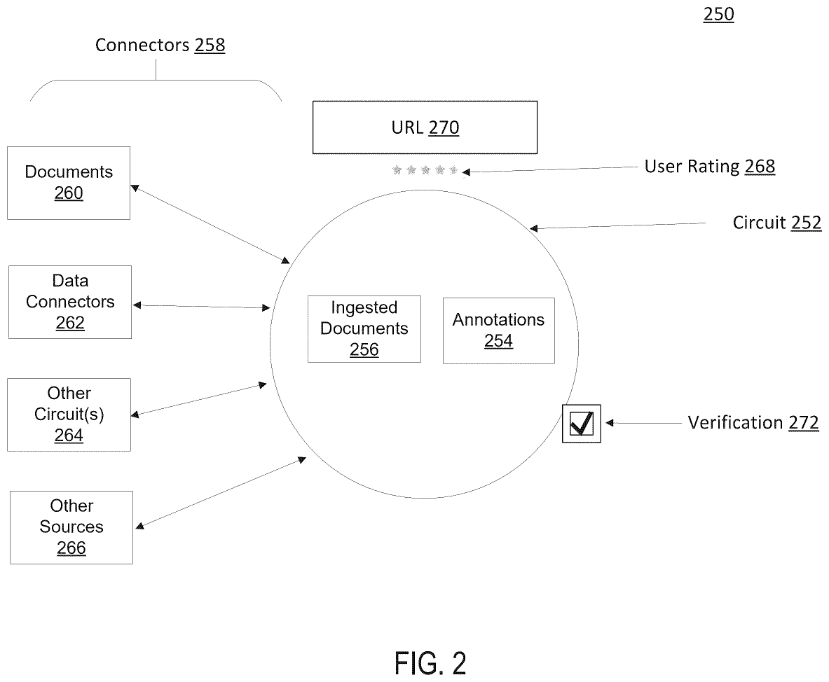

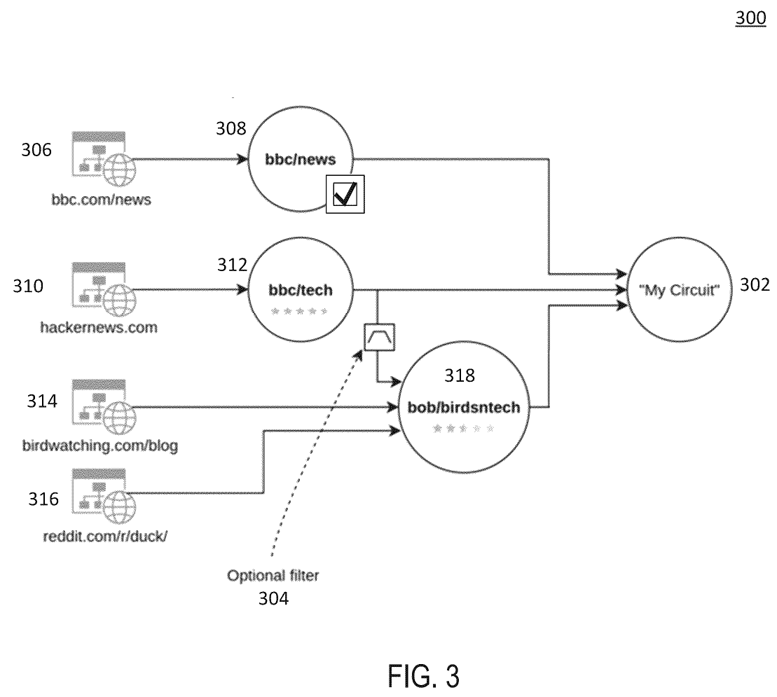

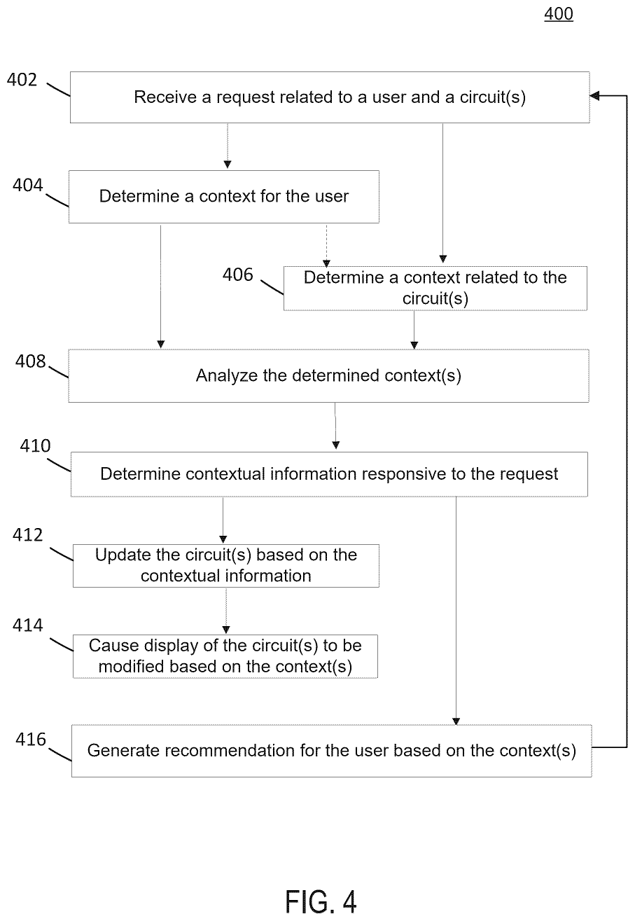

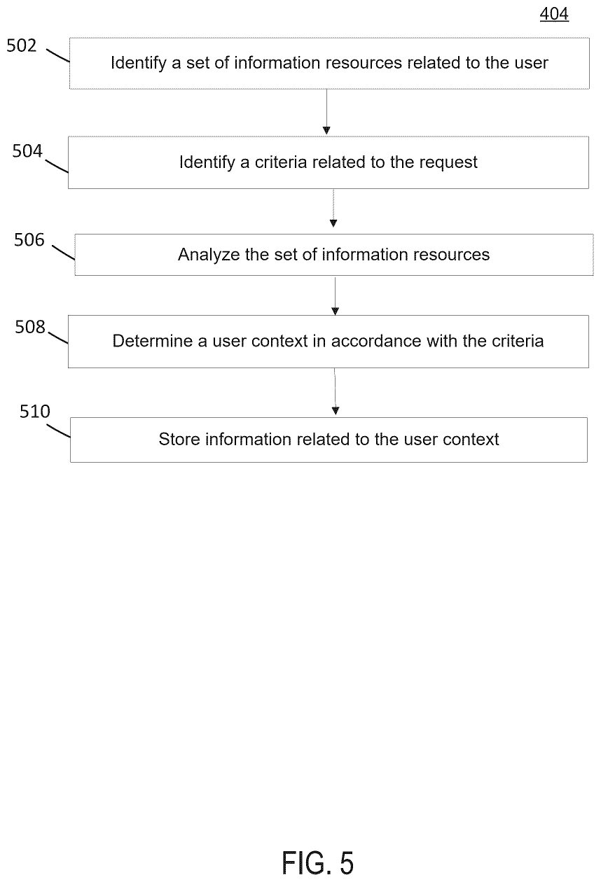

According to some embodiments, system 110 can correspond to any type of device (or UE, as discussed above), computer system, electronic platform, web portal, web site, electronically hosted network resource, and the like, or some combination thereof. In some embodiments, for example, system 100 can correspond to a third party web site (e.g., a news web site and/or application, for example) for which a user of UE 102 is electronically interacting with (e.g., at least a threshold amount of times and/or within a threshold period of time from a current time, for example). Examples of how such system 110 imparts functionality within system 100 are provided below in non-limiting example embodiments 250 and 300, depicted in FIGS. 2 and 3, respectively, and within Processes 400 and 500 in FIGS. 4 and 5, respectively.

In some embodiments, network 104 can be any type of network, such as, but not limited to, a wireless network, cellular network, the Internet, and the like (as discussed above). Network 104 facilitates connectivity of the components of system 100, as illustrated in FIG. 1A.

According to some embodiments, cloud system 106 may be any type of cloud operating platform and/or network based system upon which applications, operations, and/or other forms of network resources may be located. For example, system 106 may be a service provider and/or network provider from where services and/or applications may be accessed, sourced or executed from. For example, system 106 can represent the cloud-based architecture associated with a proprietary system provider, which has associated network resources hosted on the internet or private network (e.g., network 104), which enables (via engine 200) the information and/or electronic resource management and monitoring, as discussed herein.

In some embodiments, cloud system 106 may include a server(s) and/or a database of information which is accessible over network 104. In some embodiments, a database 108 of cloud system 106 may store a dataset of data and metadata associated with local and/or network information related to a user(s) of UE 102/system 110 and the UE 102/system 110, and the services and applications provided by cloud system 106 and/or context engine 200.

In some embodiments, for example, cloud system 106 can provide a private/proprietary management platform, whereby engine 200, discussed infra, corresponds to the novel functionality system 106 enables, hosts and provides to a network 104 and other devices/platforms operating thereon.

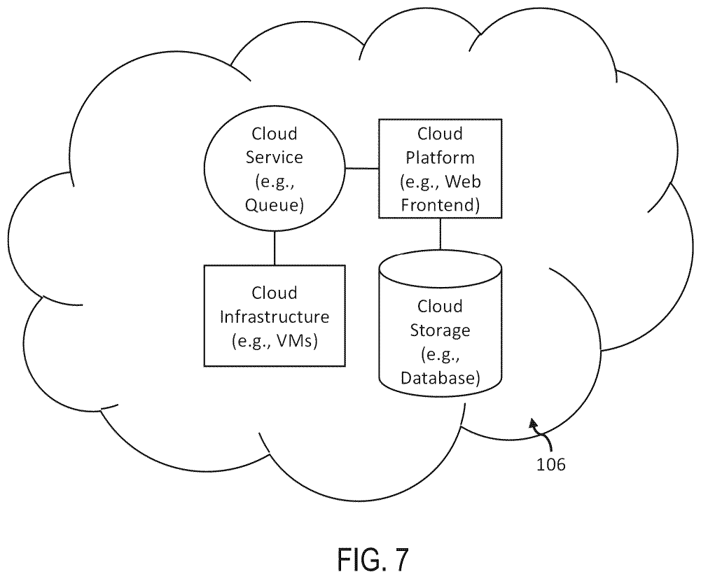

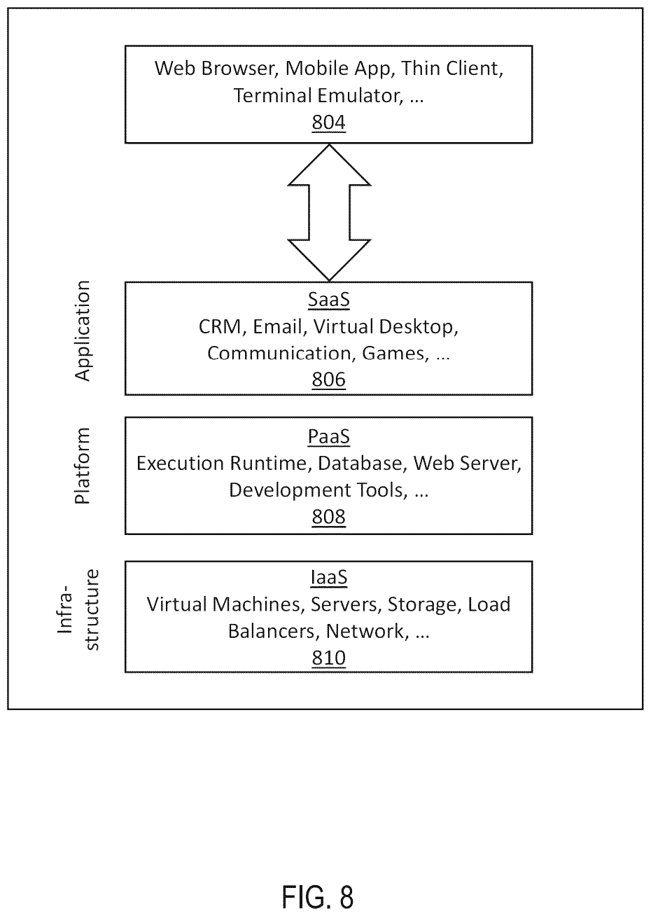

Turning to FIG. 7 and FIG. 8, in some embodiments, the exemplary computer-based systems/platforms, the exemplary computer-based devices, and/or the exemplary computer-based components of the present disclosure may be specifically configured to operate in a cloud computing/architecture 106 such as, but not limiting to: infrastructure a service (IaaS) 810, platform as a service (PaaS) 808, and/or software as a service (SaaS) 806 using a web browser, mobile app, thin client, terminal emulator or other endpoint 804. FIG. 7 and FIG. 8 illustrate schematics of non-limiting implementations of the cloud computing/architecture(s) in which the exemplary computer-based systems for administrative customizations and control of network-hosted application program interfaces (APIs) of the present disclosure may be specifically configured to operate.

Turning back to FIG. 1A, according to some embodiments, database 108 may correspond to a data storage for a platform (e.g., a network hosted platform, such as cloud system 106, as discussed supra) or a plurality of platforms. Database 108 may receive storage instructions/requests from, for example, engine 200 (and associated microservices), which may be in any type of known or to be known format, such as, for example, standard query language (SQL). According to some embodiments, database 108 may correspond to any type of known or to be known storage, for example, a memory or memory stack of a device, a distributed ledger of a distributed network (e.g., blockchain, for example), a look-up table (LUT), and/or any other type of secure data repository

Context engine 200, as discussed above and further below in more detail, can include components for the disclosed functionality. According to some embodiments, context engine 200 may be a special purpose machine or processor, and can be hosted by a device on network 104, within cloud system 106 and/or on UE 102. In some embodiments, engine 200 may be hosted by a server and/or set of servers associated with cloud system 106.

According to some embodiments, as discussed in more detail below, context engine 200 may be configured to implement and/or control a plurality of services and/or microservices, where each of the plurality of services/microservices are configured to execute a plurality of workflows associated with performing the disclosed functionality. Non-limiting embodiments of such workflows are provided below.

According to some embodiments, as discussed above, context engine 200 may function as an application provided by cloud system 106. In some embodiments, engine 200 may function as an application installed on a server(s), network location and/or other type of network resource associated with cloud system 106. In some embodiments, engine 200 may function as an application installed and/or executing on UE 102 (e.g., engine 200 accessing a CPU/GPU and/or neural processing unit (NPU) of the UE, for example). In some embodiments, such application may be a web-based application accessed by UE 102 and/or devices over network 104 from cloud system 106. In some embodiments, engine 200 may be configured and/or installed as an augmenting script, program or application (e.g., a plug-in or extension) to another application or program provided by cloud system 106 and/or executing on UE 102.

As illustrated in FIG. 1B, according to some embodiments, context engine 200 includes identification module 202, determination module 204; circuit module 206 and recommendation module 208. It should be understood that the engine(s) and modules discussed herein are non-exhaustive, as additional or fewer engines and/or modules (or sub-modules) may be applicable to the embodiments of the systems and methods discussed. More detail of the operations, configurations and functionalities of engine 200 and each of its modules, and their role within embodiments of the present disclosure will be discussed below.

Turning to FIG. 2, depicted is non-limiting example 250, which depicts an example embodiment for how electronic information can be mined for curation of a circuit for a user. As discussed herein, example 250 depicts the components that can be used to form a circuit 252. Example 252 includes circuit 252, annotations 254, ingested documents references 256 (referred to as ingested documents, interchangeably), connectors 258, individual documents 260 (or documents, used interchangeably), data connector(s) 262, other circuit(s) 264, other sources 266, user rating 268, uniform resource locator (URL) 270 and owner verified item (verification) 272.

In some embodiments, the annotations 254 can correspond to “circuit-specific annotations,” which can involve, but not be limited to, a combination of document metadata such as ownership information, creation time, permissions, and the like, as well as, but not limited to, information added by a user to extend, correct, clarify and/or add value to the document, and information provided through various automated processing steps, as discussed below at least with reference to FIGS. 4-6.

It should be noted that example 250 is a non-limiting example, and not all components are required for the compilation of a circuit 252—for example, other circuits 264 may not be required or requested for generation of a circuit 252.

By way of a non-limiting example, the compilation and/or updating of circuit 252 can involve the retrieval of information from documents 260, data connectors 262, other circuits 264 and/or other sources 266. As provided below in more detail, such data can be analyzed and compiled into ingested documents 256, which can be hosted and provided via circuit 252. In some embodiments, such documents 256 can be subject to modifications—for example, a user author (and/or, e.g., other subscribed users) of the circuit 252 can provide circuit-specific annotations that enable customization of the ingested documents 256 (e.g., inline edits to document version available within circuit 252).

In some embodiments, as discussed herein, the circuit can be hosted on a web page, which can be accessible via the direct access URL 270. Such URL 270 location may be accessible via a search engine search and/or direct access provided by a message that includes such URL 270. In some embodiments, the URL 270 for circuit 252 can be categorized, which can be indicated in the URL address. For example, categories can include, but are not limited to, company, organization, news, unverified, user, country, and the like. For example, a URL for Company C may be: circuit.ai/C/CompanyX/ . . . , whereby “C” denotes the category of a “company” and “Company X” is the unique company name. In some embodiments, categorization may be tied to whether a user (e.g., Company X) is verified, as discussed below. For example, unverified users may not have a unique category designation in their URL address.

In some embodiments, feedback can be provided to the circuit 252 by other users, whereby such functionality is represented by user rating 268. For example, users who “follow” or subscribe to a circuit 252 can provide feedback via any type of rating, inclusive of comments (not shown).

In some embodiments, the user author (e.g., owner) of the circuit 252 can be “verified”—item 272. In some embodiments, for example, for a circuit 252 and/or user author (owner) to be verified a verification request may be submitted, which can involve providing proof of identity, such as a government-issued identification (ID) (and/or evidence of notability or public interest, for example—which can include links to notable news articles, a significant number of followers, or a threshold satisfying online presence (e.g., a threshold amount of followers on social media, for example)). Accordingly, the disclosed framework can deploy varying forms of criteria and application procedures to perform the verification, which can aid in establishing the authenticity of the user's account, and/or notoriety of the circuit (e.g., marking it with a blue checkmark or badge, for example, as depicted in item 272).

As discussed above, according to some embodiments, circuit 252 is a collection of ingested documents 256. Such ingested documents 256 can be collected, retrieved, extracted and/or otherwise identified from network sources (referred to as “target sources”) via inbound connectors 258, whereby such sources can include, for example, documents 256, data connectors 262, other circuits 264, other sources 266, and the like, or some combination thereof.

For example, circuit 256 can include information from other circuits 264, whereby such other circuits 264 information can be linked to circuit 252. In some embodiments, circuit 252 may not duplicate the information in the other circuits 264 (e.g., which can reduce storage/memory usage, as already hosted data can be pointed to via the other circuits' URL, for example). In some embodiments, the information/documents from the other circuits 264 may be stored as created versions of such information/documents.

According to some embodiments, as discussed herein, documents 260 (e.g., electronic documents from electronic, network sources) are collections of information. For example, a document can be, but is not limited to, a word document, web page, chat thread, image, video, multimedia file, object, item, article, Real Simple Syndication (RSS) feed, and/or any other type of data and/or metadata can be rendered and/or viewed by a user, device and/or application. For example, documents 260 can be an article from the New York Times®, a chat transcript from a user's Facebook® page, an image post or story from the user's Instagram® page, and the like.

In some embodiments, such documents 260, as well as other information from components 262, 264 and/or 266), once input as ingested documents 256, can be subject to annotations 254. As provided herein, annotations 254 can be inline (e.g., within the documents) and/or as whole-document annotations (e.g., edits the document name and other metadata, and/or provide descriptive information about the document, for example). In some embodiments, annotations 254 can be automatically accepted, proposed and/or rejected, and in some embodiments, annotations 254 can be subject to their own annotations (or comments).

In some embodiments, annotations 254 can be layered within a circuit. For example, if a circuit A (e.g., circuit 252) is linked to circuit B (e.g., other circuit 264), and a document 256 in circuit B is annotated within circuit B, an author of circuit A can add additional annotations 254. In some embodiments, such annotations 254 of the document in circuit B may not be viewable by subscribers of circuit A.

In some embodiments, annotations 254 can result in a new document being created within a circuit 252 and/or within other circuits that link to circuit 252 (as discussed in FIG. 3, infra). In some embodiments, at least a portion of the metadata for an annotated document may be recompiled based on the combined document with annotations by the document ingestion, as discussed below.

In another example, if a user has two local circuits, where each circuit is subject to added annotations 254 to the same document within each circuit (circuit 1 has the document, and circuit 2 references the document in circuit 1), such annotations can cause two separate “document +layer” instances—that is, there is one instance each circuit, such that if/when such two circuits are referenced by a third circuit, the same document (from each circuit) can show up as two separate documents, both linking back to the original document (in circuit 1). In some embodiments, such two separate documents can be merged into a third document, thereby combining the annotations of both, through the application of user input, LLMs and/or other AI/ML algorithms.

In some embodiments, data connectors 262 correspond to customization of connectors 258, which enable owners of a circuit 252 to specifically request and/or customize specific types, forms, quantities of information. For example, Company X, dealing with the import/export business, may request data from wholesalers of item Y. This can be realized via data connector 262, which can be determined automatically based on a context of Company X and/or circuit 252, as discussed herein.

In some embodiments, other sources 266 can correspond to any type of known or to be known type or form of data/content source—for example, databases, APIs, web scrapings, surveys, log files, social media fees, data portals, market data, and the like, or some combination thereof. For example, in some embodiments, such sources 266 can include system 110, UE 102, database 108 or another location. A typical destination for the resulting document is a circuit, but can also be system 110, UE 102, database 108 or another location.

According to some embodiments, connectors 258 operate as executable workflows (e.g., executable instructions that cause engine 200 to establish such specific pathways, discussed infra) that enable the over-network retrieval and ingestion of documents (260-266) from target sources into circuit (as ingested documents 256). As discussed herein, connectors 258 can be inbound and/or outbound (e.g., cause data to be ingested to a circuit source, and/or provide data to a target source from a circuit, and the like). In some embodiments, a connector 258 can cause the performance of and/or enable operations to extract relevant data from a target data source—for example, a PDF connector can extract text, tables and images, and add relevant context and usage information. Such data can be subject to ingestion processing via engine 200, discussed infra in relation to the steps of Process 400). Further discussion of connectors 258 is provided below in relation to Process 400.

Turning to FIG. 3, depicted is example 300, which provides an example of a circuit 302 that can be generated from target sources (306, 310, 314 316) and corresponding circuits (308, 312 318, respectively). Such circuits 308, 312 and 318 provide another example of the other circuits 264 from FIG. 2, discussed supra.

According to some embodiments, for a given circuit, users interacting with a circuit can have different roles. A role higher in the hierarchy can provide read/write access rights and/or functionality to perform more operations, and/or have increased access to circuit documents than a role lower in the hierarchy. Accordingly, in some embodiments, how a user is slotted/assigned/subscribed within the hierarchy can provide them with modified versions of read/write privileges as they relate to accessing, interacting with and/or viewing circuit information.

In some embodiments, a hierarchy order can include, in descending order of access/privileges: owner, administrator (Admin), automator, author, contributor and user.

In some embodiments, an owner owns a circuit, and can have privileges as a super-admin. An owner involves functionality for enabling other users as administrators, and can initiate the transfer of ownership to another user.

In some embodiments, administrators can be provided permissions by an owner, such as, for example, elevated privileges to assign authors, add new connectors, customize connectors, change settings, change subscriptions settings, and the like.

In some embodiments, an automator can create new data connectors 262, and request an admin make them live/active for ingestion.

In some embodiments, an author can add documents to a circuit and organize content (e.g., request and/or cause the operations of engine 200 to perform the ingestion of targeted sources, for example).

In some embodiments, a contributor can create circuit annotations, accept circuit annotations from other users, leave feedback, provide ratings, and the like; and

In some embodiments, a user is a consumer of a circuit (e.g., a subscriber, for example). In some embodiments, such a role can involve functionality to propose and/or comment on annotations for documents in a circuit.

In some embodiments, each user can have their own circuit (e.g., “My Circuit” 302, as in FIG. 3), for which they are an owner. Other circuits (e.g., circuits 308, 312 and 318, for example) can be owned by other users that have created them. Each circuit has its own user account (e.g., owner account) that has ownership, and corresponding privileges from the hierarchy associated therewith.

Accordingly, FIG. 3 depicts an example where circuit 302 is configured to ingest documents from circuits 308, 312 and 318. As depicted, for example, circuit 308 can include documents from source 306; circuit 312 includes documents from source 310; and circuit 318 includes documents from sources 314 and 316, and circuit 312. In some embodiments, the connectors enabling ingestion from such sources and circuits can include functionality for filtering content—for example, circuit 318 only may requests a portion of the documents in circuit 312; therefore, filter 304 can filter and identify such portion during extraction and ingestion into circuit 318.

Turning to FIG. 4, Process 400 provides non-limiting example embodiments for the disclosed systems and methods. As discussed in detail below, Process 400 provides non-limiting example embodiments for content circuit curation, dissemination, updating and/or sharing over a network based on deterministically compiled user-based and/or circuit-based contexts, which can enable consuming users to be provided with the most current, accurate digital information that is temporally, socially, logically and emotionally to the user's current intent when consuming/requesting content via their device(s). As provided below, Process 400 provides capabilities related to the search for information, and functionality for accurately and efficiently mapping information into a context for consumption by the user via a circuit(s).

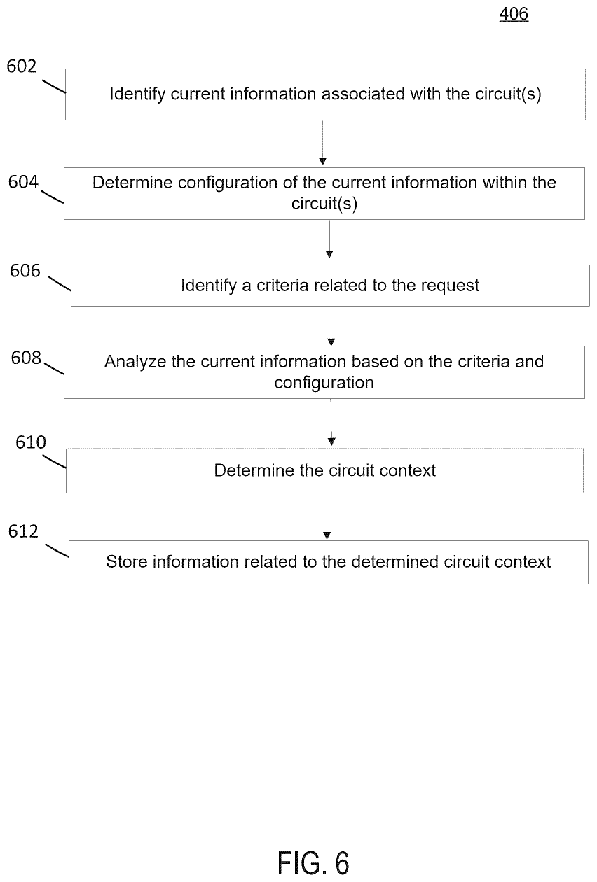

According to some embodiments, Step 402 of Process 400 can be performed by identification module 202 of context engine 200; Steps 404-410—(and sub-steps 502-510 of Step 404 in FIG. 5, and sub-steps 602-612 of Step 406 in FIG. 6, discussed infra) can be performed by determination module 204; Steps 412 and 414 can be performed by circuit module 206; and Step 416 can be performed by recommendation module 208.

According to some embodiments, Process 400 begins with Step 402 where engine 200 can receive a request related to a user and/or a circuit(s). According to some embodiments, the request can be in relation to the search for a circuit, creation of a circuit, updating a circuit, annotating a circuit, searching for documents (as discussed above), and the like, or some combination thereof. In some embodiments, the request may be in relation to, but not limited to, real-world user actions (e.g., a user visiting a location and/or the user's current location, for example), digital actions by the user (e.g., websites, documents and/or circuits interacted with by the user, the user's circuits (e.g., “My Circuit,” as discussed above), the role of the user respective to the circuit (e.g., owner, for example), a time period (e.g., update a circuit and/or user/circuit context, as discussed infra based on a time and/or time-lapsed since a circuit update/creation, and the like), and the like, or some combination thereof.

For example, in some embodiments, a user may request access to a circuit (e.g., navigating the URL of a circuit, and/or entering a search within a search engine and/or within an LLM interface asking a question related to a topic), which, as discussed above, may be a layered circuit with other circuits; therefore, the request can involve information related to the user's information (or account information—for example, demographics, behavior, and the like) and the circuit information, which can be for the circuit and/or across a number of layered/reference circuits.

In response to the request from Step 402, engine 200 can determine a context for the user (user context or user-based context, used interchangeably), as in Step 404, and/or determine a context for the circuit(s) (e.g., circuit context or circuit-based context, used interchangeably), as in Step 404.

In some embodiments, engine 200 can perform Step 404, whereby the context determination for the circuit in Step 406 is based on the determined user context, as indicated via the dashed-line in FIG. 4. In some embodiments, the update and display of the circuit(s), as discussed in Step 412-414, infra, and/or the recommendations via Step 416, discussed infra, may be based on the user context (Step 404), circuit context (Step 406) and/or some combination thereof. In some embodiments, such basis may be based on the request (e.g., a user provides a query that triggers a user-based context and/or circuit context update), user preferences and/or AI/ML determinations, as discussed herein. Accordingly, as provided herein, such contextual awareness allows for adaptive interfaces, smarter recommendations, and more efficient completion of user goals, ultimately enhancing the overall user experience.

According to some embodiments, a user context refers to the information and circumstances surrounding a user's interaction with a system, application and/or service (e.g., a circuit, circuit application, user's device, their real-world location, digital activities, demographics, identity (ID), account information, behavior, and the like, or some combination thereof). User context can encompass various factors that can contextualize and/or define the user' current situation, needs and/or intentions (as per the request, as discussed infra). As provided herein, by considering user context, engine 200 can provide personalized, relevant and timely circuit experiences for the user (e.g., via an application and/or browser interface, for example, as discussed below at least in relation to Step 416).

Thus, turning to FIG. 5, Steps 502-510, which are sub-steps of Step 404, are discussed, which provide non-limiting embodiments for operations engine 200 can perform to determine the user context.

According to some embodiments, in Step 502, engine 200 can identify a set of information resources related to the user. In some embodiments, such information resources can correspond to data, metadata, files, objects, items, webpages, websites, applications, UIs, and the like, that the user has interacted with, stored, have had included in a circuit, behavior information of the user, and the like. Such resources can include, but are not limited to, circuits, documents, connectors, account information, annotations, contributions to documents, web pages, applications, and the like, or some combination thereof. For example, as depicted in FIGS. 2 and 3, the information utilized to compile and/or populate a circuit can be at least part of the information resources for the user. In another non-limiting example, data/metadata related to the user's interactions with different circuits, as well as the user's responses to questions to clarify and/or add intent (e.g., via an LLM chatbot, as discussed below), can be identified via Step 502, and serve as at least a portion of the set of information resources.

In Step 504, engine 200 can identify (or determine) a criteria related to the request (from Step 402, supra). Such criteria can be related to, but not limited to, a time, date, user ID, user role in a circuit (e.g., owner, contributor, and the like, as discussed above), type of circuit (e.g., public, private, and/or subscription-based, and the like), position within hierarchy of layered circuits (e.g., is it the main circuit node or a circuit being referenced via an ingested document, as discussed above), and the like, or some combination thereof. Thus, as provided herein, the criteria can indicate a trigger for causing the request to be compiled and executed, as per Step 402—for example, the user is searching a network location (e.g., web site) that engine 200 determines deviates from their pattern of activity, yet the person has visited with at n times, thereby satisfying a frequency threshold; therefore, the request from Step 402 can be triggered.

In Step 506, engine 200 can analyze the set of information resources. In some embodiments, engine 200 can perform a computational analysis of the set of information resources based on the criteria (and/or information from the request from Step 402). According to some embodiments, engine 200 can implement any type of known or to be known computational analysis technique, algorithm, mechanism or technology to perform such analysis.

In some embodiments, engine 200 may execute and/or include a specific trained artificial intelligence/machine learning model (AI/ML), a particular machine learning model architecture, a particular machine learning model type (e.g., convolutional neural network (CNN), recurrent neural network (RNN), autoencoder, support vector machine (SVM), and the like), or any other suitable definition of a machine learning model or any suitable combination thereof.

In some embodiments, engine 200 may leverage a large language model (LLM), whether known or to be known. A LLM is a type of AI system designed to understand and generate human-like text based on the input it receives. The LLM can implement technology that involves deep learning, training data and natural language processing (NLP). Large language models are built using deep learning techniques, specifically using a type of neural network called a transformer. These networks have many layers and millions or even billions of parameters. LLMs can be trained on vast amounts of text data from the internet, books, articles, and other sources to learn grammar, facts, and reasoning abilities. The training data helps them understand context and language patterns. LLMs can use NLP techniques to process and understand text. This includes tasks like tokenization, part-of-speech tagging, and named entity recognition.

LLMs can include functionality related to, but not limited to, text generation, language translation, text summarization, question answering, conversational AI, text classification, language understanding, content generation, and the like. Accordingly, LLMs can generate, comprehend, analyze and output human-like outputs (e.g., text, speech, audio, video, and the like) based on a given input, prompt or context. Accordingly, LLMs, which can be characterized as transformer-based LLMs, involve deep learning architectures that utilizes self-attention mechanisms and massive-scale pre-training on input data to achieve NLP understanding and generation. Such current and to-be-developed models can aid AI systems in handling human language and human interactions therefrom.

In some embodiments, engine 200 may be configured to utilize one or more AI/ML techniques chosen from, but not limited to, computer vision, feature vector analysis, decision trees, boosting, support-vector machines, neural networks, nearest neighbor algorithms, Naive Bayes, bagging, random forests, logistic regression, and the like. By way of a non-limiting example, engine 200 can implement an XGBoost algorithm for regression and/or classification to analyze the request and/or user information, as discussed herein.

In some embodiments and, optionally, in combination of any embodiment described above or below, a neural network technique may be one of, without limitation, feedforward neural network, radial basis function network, recurrent neural network, convolutional network (e.g., U-net) or other suitable network. In some embodiments and, optionally, in combination of any embodiment described above or below, an implementation of Neural Network may be executed as follows:
a. define Neural Network architecture/model,
b. transfer the input data to the neural network model,
c. train the model incrementally,
d. determine the accuracy for a specific number of timesteps,
e. apply the trained model to process the newly-received input data,
f. optionally and in parallel, continue to train the trained model with a predetermined periodicity.

In some embodiments and, optionally, in combination of any embodiment described above or below, the trained neural network model may specify a neural network by at least a neural network topology, a series of activation functions, and connection weights. For example, the topology of a neural network may include a configuration of nodes of the neural network and connections between such nodes. In some embodiments and, optionally, in combination of any embodiment described above or below, the trained neural network model may also be specified to include other parameters, including but not limited to, bias values/functions and/or aggregation functions. For example, an activation function of a node may be a step function, sine function, continuous or piecewise linear function, sigmoid function, hyperbolic tangent function, or other type of mathematical function that represents a threshold at which the node is activated. In some embodiments and, optionally, in combination of any embodiment described above or below, the aggregation function may be a mathematical function that combines (e.g., sum, product, and the like) input signals to the node. In some embodiments and, optionally, in combination of any embodiment described above or below, an output of the aggregation function may be used as input to the activation function. In some embodiments and, optionally, in combination of any embodiment described above or below, the bias may be a constant value or function that may be used by the aggregation function and/or the activation function to make the node more or less likely to be activated.

In Step 508, based on the analysis from Step 506, engine 200 can determine a context for the user (“user context”), which can identify, for example, topic(s), target sources, user information, and the like. In Step 510, in some embodiments, such user circuit context can be stored in association with the circuit(s) and/or an account of the user in database 108, as discussed above.

Turning back to Process 400 of FIG. 4, engine 200 can determine the context related to the circuit(s). According to some embodiments, circuit context refers to the surrounding information, embeddings and/or metadata that provide a deeper understanding of the circuit's (or circuits') meaning, purpose and/or relevance. In some embodiments, such circuit context can be based on, but not limited to, the circuit owner/author (and/or other roles of the user and/or other users), creation date, version history, format, intended audience, and the like. Moreover, in some embodiments, a circuit context may encompass the schema definition of the circuit, data types within the circuit, relationships between elements in the circuit, the broader platform, network location and/or application in which the circuit is hosted/accessed, and the like, or some combination thereof. Additionally, circuit context can involve the circuit's place within a larger corpus of information, its relevance to specific topics, projects, other circuits and/or documents referenced/ingested therein, and any associated tags or categories, and the like, or some combination thereof.

Accordingly, as discussed herein, a circuit's context provides contextual information that can aid engine 200 in interpreting, organizing and utilizing documents and/or the circuit as a whole more effectively, enabling better decision-making, search capabilities, and data management, which all will increase user engagement with the circuit and/or across the circuit platform(s).

Thus, turning to FIG. 6, Steps 602-612, which are sub-steps of Step 406, are discussed, which provide non-limiting embodiments for operations engine 200 can perform to determine the circuit context of the circuit(s).

According to some embodiments, in Step 602, engine 200 can identify the current information associated with a circuit. This information can correspond to the current version of the circuit that is hosted on the network, as discussed above, at least in relation to FIGS. 2 and 3. For example, the current information can correspond to, but not be limited to, documents, data connectors, other circuits, other sources, ingested documents, annotations, user rating, and the like, as depicted in FIG. 2 (that are associated with the circuit at a time proximate (e.g., at or substantially the same time, for example) to when the request in step 402 was received). In some embodiments, as mentioned above, the information can further include the user context (from Step 404, discussed supra).

In Step 604, engine 200 can determine a configuration of the current information within the circuit. This can correspond to, for example, how the documents are ingested and/or organized within the circuit, where the annotations are located (e.g., in the circuit and/or in another circuit for where a document ingested is referenced from, for example), and the like. Further, in some embodiments, the configuration may correspond to a hierarchy of whether the circuit is referenced by another circuit, or vice versa (e.g., whether other circuits are ingested by the instant circuit). Thus, in some embodiments, the manner in which a circuit, its ingested information and/or referenced information/circuits can be determined via Step 604 (e.g., the object model and/or type of object model in which the data in the circuit is organized, for example).

In Step 606, engine 200 can identify (or determine) a criteria related to the request (from Step 402, supra). Such identification can be performed in a similar manner as discussed in relation to Step 504, discussed supra.

In Step 608, engine 200 can analyze the current information (from Step 602) based on the criteria (from Step 606) and the configuration (from Step 604); and in some embodiments (based on information from the request from Step 402). According to some embodiments, engine 200 can implement any type of known or to be known computational analysis technique, algorithm, mechanism or technology to perform such analysis, which can be performed via any of the AI/ML and/or LLM model-based analysis discussed in relation to Step 506, discussed supra.

In Step 610, based on the computational analysis of Step 608, engine 200 can determine the circuit context for the circuit(s). As discussed above, such circuit context can indicate, for example, the focus of a circuit, which can be used to narrow down information or put a specific focus on it for users of that circuit, as discussed below respective subsequent steps of Process 400.

And, in Step 612, in some embodiments, such circuit context can be stored in association with the circuit(s) and/or a user account (e.g., owner account, for example) in database 108, as discussed above.

Turning back to Process 400, upon completion of Steps 404 and/or 406, engine 200 can proceed to Step 408, where the determined contexts are analyzed. In some embodiments, engine 200 can analyze the user context and (or) circuit context by implementing and/or executing any type of known or to be known computational analysis technique, algorithm, mechanism or technology to perform such analysis, which can be performed via any of the AI/ML and/or LLM model-based analysis discussed in relation to Step 506, discussed supra.

In some embodiments, the analysis can involve weighting the user context more than the circuit context, or vice versa. For example, if the user is an owner of the circuit, then the user context may be weighted more than the circuit context. However, in another example, if the user is not a subscriber of a circuit, and merely a “free” user, then the circuit context may be weighted more than the determined user context. And, in another non-limiting example, if the request is to a circuit from a non-logged in user, or a search engine, then, in some embodiments, only the circuit context may be applied, because the user context may be unknown due to the user being unknown.

In Step 410, based on the computational analysis performed in Step 408, engine 200 can determine contextual information responsive to the request. In some embodiments, the contextual information can correspond to a global and/or individual-based context. For example, if actions within two circuits would evolve a user's context in opposite directions, those components are stored in a user's context related to the circuits, but canceled out for the user's global context, allowing a user themselves to have slightly different contexts when working in different circuits.

Thus, the contextual information can be a combined (user- and circuit-based) context that can be utilized to personalize the information/content within circuits, which can range from circuit pages, UIs, circuit editing (adding new circuits, connectors, and the like), chat capabilities, and the like. Such combined context can enable determinations for what the information within a circuit is shown to a viewing user (e.g., the user), as well as how it is conveyed/rendered to the user.

In some embodiments, such contextual information can be stored in database 108, as discussed above, which can be in relation to the circuit(s) and/or the user (or other users—for example an owner user of the circuit).

Accordingly, in Step 412, engine 200 can update the circuit(s) (or a portion of the circuits identified in Step 402) based on the contextual information. Such updating can include, but is not limited to, ingesting new documents, ingesting updated versions of documents and/or annotations, establishing new connectors, and the like. In some embodiments, such updating can also involve removing connectors, documents, annotations, and the like, as they may be deemed to not be related to the context (from Steps 410, 404 and/or 410). In some embodiments, such updating may involve removing certain documents and/or information from being viewable, thereby maintaining the data within the circuit, but modifying how the circuit can be viewed (e.g., UI), such that the data is not accessible but retrievable upon a subsequent request (via Step 402) that indicates it is then contextually related. In some embodiments, such updating may also involve removing certain content (e.g., documents, annotations and/or displayed contexts, for example) that is determined to not match the combined context (e.g., a similarity measure falls below a similarity threshold for the content versus the combined context via an AI/ML based similarity analysis executed by engine 200).

In Step 414, engine 200 can cause the display of the circuit(s) to be rendered according to the modifications/updates from Step 412. As discussed above, how data is displayed, and which manner it is conveyed can be altered. For example, if a document is typically displayed on the user's device, if the user context indicates the user is driving (based on the user context portion of the combined context from Step 410), an updated version of the document (based on the circuit context portion of the combined context from Step 410) can be retrieved then audibly rendered upon the user's device accessing the corresponding circuit.

In some embodiments, the display of the updated circuit can include a portion within the UI that renders for display information related to the determined contextual information (and/or user context and/or circuit context). This can enable a user to see why certain versions and/or structured circuit configurations are provided to the user. Moreover, this can provide capabilities for the user to interact with the circuit to drive further content discover—for example, engage with an LLM chatbot that provides functionality for the user to ask, “why was my context this . . . ”, or “how can I change my context to enable other types of X content to be included in my circuit, and the like. Indeed, the overall user experience can be improved, as the reasoning for particular types and/or quantities of content can be provided to viewing users, thereby increasing the transparency as to the mechanisms that triggered the collection and/or display of such content, which can improve the trust of such viewing users.

In some embodiments, in addition to the contexts related to the user being depicted (e.g., from Steps 410, 404 and/or 408), such contexts for other users can be displayed and interacted within via a chatbot in a similar manner.

And, in Step 416, engine 200 can generate (compile or create) electronic recommendations for the user based on the context(s) (e.g., combined context, user context and/or circuit context). Such recommendations can be electronic messages, pop-ups, notifications and/or alerts that can correspond to, but not be limited to, discovered content, new connectors, removal of connectors, new documents to ingest, removal of ingested documents, and the like, or some combination thereof. Such recommendations can cause the user to navigate to other circuits, for which they can subscribe, such that such subscribed circuits can then be ingested (as discussed above in at least FIGS. 2-3, for example). For example, engine 200 can search for content based on the context (from Steps 410, 404 and/or 408) and determine digital content that is to be ingested to update the circuit(s), documents, connectors and/or annotations therein.

Moreover, such recommendations can be actions that enable the user to approve, deny and/or interact with LLMs that enable further refinement of the user's context. As discussed above.

In some embodiments, such recommendations can involve engine 200 accessing new documents (and/or existing document versions previously ingested into a circuit(s)) and extracting snippets therefrom, for which annotations can be recommended. Such recommended annotations can be provided via the chatbot interface, which can be approved, denied, modified, discussed with via the LLM backing the chatbot, discussed with via other users, and the like, such that upon their approval to the document/circuit, they can be shared with other users/circuits via the circuit.

Accordingly, as discussed herein, the disclosed framework can deterministically compute a context, which can be a user-based and/or circuit-based context, that can be leveraged to provide and/or recommend information and/or actions to users over a network, thereby facilitating improved interactions with circuits and/or circuit hosted information.

FIG. 9 is a schematic diagram illustrating a client device showing an example embodiment of a client device that may be used within the present disclosure. Client device 900 may include many more or less components than those shown in FIG. 9. However, the components shown are sufficient to disclose an illustrative embodiment for implementing the present disclosure. Client device 900 may represent, for example, UE 102 discussed above at least in relation to FIG. 1A.

As shown in the figure, in some embodiments, Client device 900 includes a processing unit (CPU) 922 in communication with a mass memory 930 via a bus 924. Client device 900 also includes a power supply 926, one or more network interfaces 950, an audio interface 952, a display 954, a keypad 956, an illuminator 958, an input/output interface 960, a haptic interface 962, an optional global positioning systems (GPS) receiver 964 and a camera(s) or other optical, thermal or electromagnetic sensors 966. Device 900 can include one camera/sensor 966, or a plurality of cameras/sensors 966, as understood by those of skill in the art. Power supply 926 provides power to Client device 900.

Client device 900 may optionally communicate with a base station (not shown), or directly with another computing device. In some embodiments, network interface 950 is sometimes known as a transceiver, transceiving device, or network interface card (NIC).

Audio interface 952 is arranged to produce and receive audio signals such as the sound of a human voice in some embodiments. Display 954 may be a liquid crystal display (LCD), gas plasma, light emitting diode (LED), or any other type of display used with a computing device. Display 954 may also include a touch sensitive screen arranged to receive input from an object such as a stylus or a digit from a human hand.

Keypad 956 may include any input device arranged to receive input from a user. Illuminator 958 may provide a status indication and/or provide light.

Client device 900 also includes input/output interface 960 for communicating with external. Input/output interface 960 can utilize one or more communication technologies, such as USB, infrared, Bluetooth™, or the like in some embodiments. Haptic interface 962 is arranged to provide tactile feedback to a user of the client device.

Optional GPS transceiver 964 can determine the physical coordinates of Client device 900 on the surface of the Earth, which typically outputs a location as latitude and longitude values. GPS transceiver 964 can also employ other geo-positioning mechanisms, including, but not limited to, triangulation, assisted GPS (AGPS), E-OTD, CI, SAI, ETA, BSS or the like, to further determine the physical location of client device 900 on the surface of the Earth. In one embodiment, however, Client device 900 may through other components, provide other information that may be employed to determine a physical location of the device, including for example, a MAC address, Internet Protocol (IP) address, or the like.

Mass memory 930 includes a RAM 932, a ROM 934, and other storage means. Mass memory 930 illustrates another example of computer storage media for storage of information such as computer readable instructions, data structures, program modules or other data. Mass memory 930 stores a basic input/output system (“BIOS”) 940 for controlling low-level operation of Client device 900. The mass memory also stores an operating system 941 for controlling the operation of Client device 900.

Memory 930 further includes one or more data stores, which can be utilized by Client device 900 to store, among other things, applications 942 and/or other information or data. For example, data stores may be employed to store information that describes various capabilities of Client device 900. The information may then be provided to another device based on any of a variety of events, including being sent as part of a header (e.g., index file of the HLS stream) during a communication, sent upon request, or the like. At least a portion of the capability information may also be stored on a disk drive or other storage medium (not shown) within Client device 900.

Applications 942 may include computer executable instructions which, when executed by Client device 900, transmit, receive, and/or otherwise process audio, video, images, and enable telecommunication with a server and/or another user of another client device. Applications 942 may further include a client that is configured to send, to receive, and/or to otherwise process gaming, goods/services and/or other forms of data, messages and content hosted and provided by the platform associated with engine 200 and its affiliates.

As used herein, the terms “computer engine” and “engine” identify at least one software component and/or a combination of at least one software component and at least one hardware component which are designed/programmed/configured to manage/control other software and/or hardware components (such as the libraries, software development kits (SDKs), objects, and the like).

Examples of hardware elements may include processors, microprocessors, circuits, circuit elements (e.g., transistors, resistors, capacitors, inductors, and so forth), integrated circuits, application specific integrated circuits (ASIC), programmable logic devices (PLD), digital signal processors (DSP), field programmable gate array (FPGA), logic gates, registers, semiconductor device, chips, microchips, chip sets, and so forth. In some embodiments, the one or more processors may be implemented as a Complex Instruction Set Computer (CISC) or Reduced Instruction Set Computer (RISC) processors; ×86 instruction set compatible processors, multi-core, or any other microprocessor or central processing unit (CPU). In various implementations, the one or more processors may be dual-core processor(s), dual-core mobile processor(s), and so forth.

Computer-related systems, computer systems, and systems, as used herein, include any combination of hardware and software. Examples of software may include software components, programs, applications, operating system software, middleware, firmware, software modules, routines, subroutines, functions, methods, procedures, software interfaces, application program interfaces (API), instruction sets, computer code, computer code segments, words, values, symbols, or any combination thereof. Determining whether an embodiment is implemented using hardware elements and/or software elements may vary in accordance with any number of factors, such as desired computational rate, power levels, heat tolerances, processing cycle budget, input data rates, output data rates, memory resources, data bus speeds and other design or performance constraints.

For the purposes of this disclosure a module is a software, hardware, or firmware (or combinations thereof) system, process or functionality, or component thereof, that performs or facilitates the processes, features, and/or functions described herein (with or without human interaction or augmentation). A module can include sub-modules. Software components of a module may be stored on a computer readable medium for execution by a processor. Modules may be integral to one or more servers, or be loaded and executed by one or more servers. One or more modules may be grouped into an engine or an application.

One or more aspects of at least one embodiment may be implemented by representative instructions stored on a machine-readable medium which represents various logic within the processor, which when read by a machine causes the machine to fabricate logic to perform the techniques described herein. Such representations, known as “IP cores,” may be stored on a tangible, machine readable medium and supplied to various customers or manufacturing facilities to load into the fabrication machines that make the logic or processor. Of note, various embodiments described herein may, of course, be implemented using any appropriate hardware and/or computing software languages (e.g., C++, Objective-C, Swift, Java, JavaScript, Python, Perl, QT, and the like).

For example, exemplary software specifically programmed in accordance with one or more principles of the present disclosure may be downloadable from a network, for example, a website, as a stand-alone product or as an add-in package for installation in an existing software application. For example, exemplary software specifically programmed in accordance with one or more principles of the present disclosure may also be available as a client-server software application, or as a web-enabled software application. For example, exemplary software specifically programmed in accordance with one or more principles of the present disclosure may also be embodied as a software package installed on a hardware device.

For the purposes of this disclosure the term “user”, “subscriber” “consumer” or “customer” should be understood to refer to a user of an application or applications as described herein and/or a consumer of data supplied by a data provider. By way of example, and not limitation, the term “user” or “subscriber” can refer to a person who receives data provided by the data or service provider over the Internet in a browser session, or can refer to an automated software application which receives the data and stores or processes the data. Those skilled in the art will recognize that the methods and systems of the present disclosure may be implemented in many manners and as such are not to be limited by the foregoing exemplary embodiments and examples. In other words, functional elements being performed by single or multiple components, in various combinations of hardware and software or firmware, and individual functions, may be distributed among software applications at either the client level or server level or both. In this regard, any number of the features of the different embodiments described herein may be combined into single or multiple embodiments, and alternate embodiments having fewer than, or more than, all of the features described herein are possible.

Functionality may also be, in whole or in part, distributed among multiple components, in manners now known or to become known. Thus, myriad software/hardware/firmware combinations are possible in achieving the functions, features, interfaces and preferences described herein. Moreover, the scope of the present disclosure covers conventionally known manners for carrying out the described features and functions and interfaces, as well as those variations and modifications that may be made to the hardware or software or firmware components described herein as would be understood by those skilled in the art now and hereafter.

Furthermore, the embodiments of methods presented and described as flowcharts in this disclosure are provided by way of example in order to provide a more complete understanding of the technology. The disclosed methods are not limited to the operations and logical flow presented herein. Alternative embodiments are contemplated in which the order of the various operations is altered and in which sub-operations described as being part of a larger operation are performed independently.

While various embodiments have been described for purposes of this disclosure, such embodiments should not be deemed to limit the teaching of this disclosure to those embodiments. Various changes and modifications may be made to the elements and operations described above to obtain a result that remains within the scope of the systems and processes described in this disclosure.

What is claimed is:

1. A method comprising:
receiving a request related to a circuit, the request identifying information related to a user and the circuit;
determining, based at least on the user information identified by the request, a user context;
determining, based at least on the circuit information identified by the request, a circuit context;
analyzing the user context and the circuit context, and determining contextual information responsive to the request;
determining digital content based on a search of resources via the determined contextual information; and
updating the circuit based on the determined digital content, the updating causing rendering of the digital content via the circuit and providing a notification related to the determined contextual information causing such rendering.

2. The method of claim 1, wherein the updating of the circuit corresponds to modification of at least one component of the circuit, the at least one component being a document, annotation, connector and other referenced circuit.

3. The method of claim 1, wherein the contextual information comprises information indicating a topic of the digital content and a manner in which the digital content is to be rendered via the circuit.

4. The method of claim 1, further comprising:
identifying a set of information resources related to the user;
analyzing the set of information resources; and
determining the user context based further on the analysis of the set of information resources.

5. The method of claim 1, further comprising:
identifying current information related to the circuit, the current information being information associated with the circuit at a time proximate to the request;
determining a configuration of the current information;
analyzing the current information based on the configuration; and
determining the circuit context based further on the analysis of the current information.

6. The method of claim 5, wherein the analysis of the current information is further based on the user context.

7. The method of claim 1, further comprising:
determining, based on information associated with the request, a criteria, the criteria indicating trigger for causing the request to be compiled and executed, wherein the user context and the circuit context are determined in accordance with criteria.

8. The method of claim 1, further comprising:
determining, based on the analysis of the user context and the circuit context, a weighting between the user context and the circuit context, wherein the determination of the contextual information is further based on the determined weighting between the user context and the circuit context.

9. The method of claim 1, wherein the circuit is related to at least one other circuit, wherein the configuration relates to a layering of the circuit and the at least one other circuit.

10. The method of claim 1, wherein the user context, circuit context and contextual information are stored in an account in relation to at least one of the user and circuit.

11. A device comprising:
a processor configured to:
receive a request related to a circuit, the request identifying information related to a user and the circuit;
determine, based at least on the user information identified by the request, a user context;
determine, based at least on the circuit information identified by the request, a circuit context;
analyze the user context and the circuit context, and determining contextual information responsive to the request;
determine digital content based on a search of resources via the determined contextual information; and
update the circuit based on the determined digital content, the update causing rendering of the digital content via the circuit and providing a notification related to the determined contextual information causing such rendering.

12. The device of claim 11, wherein the updating of the circuit corresponds to modification of at least one component of the circuit, the at least one component being a document, annotation, connector and other referenced circuit.

13. The device of claim 11, wherein the contextual information comprises information indicating a topic of the digital content and a manner in which the digital content is to be rendered via the circuit.

14. The device of claim 11, wherein the processor is further configured to:
identifying a set of information resources related to the user;
analyzing the set of information resources; and
determining the user context based further on the analysis of the set of information resources.

15. The device of claim 11, wherein the processor is further configured to:
identifying current information related to the circuit, the current information being information associated with the circuit at a time proximate to the request;
determining a configuration of the current information;
analyzing the current information based on the configuration; and
determining the circuit context based further on the analysis of the current information.

16. The device of claim 15, wherein the analysis of the current information is further based on the user context.

17. The device of claim 11, wherein the processor is further configured to:
determining, based on information associated with the request, a criteria, the criteria indicating trigger for causing the request to be compiled and executed, wherein the user context and the circuit context are determined in accordance with criteria.

18. The device of claim 11, wherein the processor is further configured to:
determining, based on the analysis of the user context and the circuit context, a weighting between the user context and the circuit context, wherein the determination of the contextual information is further based on the determined weighting between the user context and the circuit context.

19. The device of claim 11, wherein the circuit is related to at least one other circuit, wherein the configuration relates to a layering of the circuit and the at least one other circuit.

20. A non-transitory computer-readable storage medium tangibly encoded with computer-executable instructions that when executed by a processor, perform a method comprising:
receiving a request related to a circuit, the request identifying information related to a user and the circuit;
determining, based at least on the user information identified by the request, a user context;
determining, based at least on the circuit information identified by the request, a circuit context;
analyzing the user context and the circuit context, and determining contextual information responsive to the request;
determining digital content based on a search of resources via the determined contextual information; and
updating the circuit based on the determined digital content, the updating causing rendering of the digital content via the circuit and providing a notification related to the determined contextual information causing such rendering.
